(19) United States
(12) Patent Application Publication
(10) Pub. No.: US 2024/0320018 A1
(43) Pub. Date: Sep. 26, 2024

(54) CONTENT DISTRIBUTION BASED ON A USER JOURNEY USING MACHINE LEARNING

(71) Applicant: ADOBE INC., SAN JOSE, CA (US)

(72) Inventors: Rebecca Dorothy West, Auburn, CA (US); Lauren Dest, Austin, TX (US); Mihir Naware, Redwood City, CA (US); Elliot Axel Patrick Puzenat, Le Plessis Robinson (FR); Stephen Becigneul, Levallois-Perret (FR); Alexis Tessier, Eckwersheim (FR); Roger K. Brooks, Palo Alto, CA (US); Suman Basetty, Fremont, CA (US); Kimberly K. Lenox, Orinda, CA (US); Anil Kamath, Los Altos Hills, CA (US)

(21) Appl. No.: 18/477,804

(22) Filed: Sep. 29, 2023

Related U.S. Application Data
(60) Provisional application No. 63/491,499, filed on Mar. 21, 2023.

(51) Int. Cl. G06F 9/451; G06F 30/27

(52) U.S. Cl. CPC G06F 9/453; G06F 30/27

(57) ABSTRACT

A method, non-transitory computer readable medium, apparatus, and system for content distribution are described. An embodiment of the present disclosure includes obtaining, by a user experience platform, a prompt describing an element of a content distribution campaign. A machine learning model generates a user journey based on the prompt. The user journey includes at least one touchpoint for the content distribution campaign. The user experience platform provides digital content to a user corresponding to the at least one touchpoint based on the user journey.

### CROSS-REFERENCE TO RELATED APPLICATION

This application claims the benefit, under 35 U.S.C. § 119, of the filing date of U.S. Provisional Application No. 63/491,499, filed on Mar. 21, 2023, in the United States Patent and Trademark Office. The disclosure of U.S. Provisional Application No. 63/491,499 is incorporated by reference herein in its entirety.

### BACKGROUND

In some cases, content is distributed based on meaningful information learned from data processing. Data processing refers to a collection and manipulation of data to produce the meaningful information. Machine learning is an information processing field in which algorithms or models such as artificial neural networks are trained to make predictive outputs in response to input data without being specifically programmed to do so.

Content is often provided according to a user journey, which sets out a plan for distributing content elements according to one or more touchpoints (e.g., a planned distribution of content elements via a particular communication channel at a particular time or after a particular event occurs). However, a process of identifying relevant data for a user journey and then planning the user journey based on the identified data is both time-intensive and labor-intensive. There is therefore a need in the art for a content distribution system that generates a user journey for content distribution in an efficient manner.

### SUMMARY

Embodiments of the present disclosure provide a content distribution system that uses a machine learning model to generate a user journey including a touchpoint based on a prompt. In some cases, the content distribution system provides content to a user corresponding to the touchpoint.

Accordingly, by generating the user journey using the machine learning model, the content distribution system avoids a time-consuming and labor-intensive process used by conventional content distribution systems of manually creating a user journey. Furthermore, by providing content to the user corresponding to the touchpoint, the content distribution system is able to provide targeted content to a target user in a more efficient manner than conventional content distribution systems provide.

A method, apparatus, non-transitory computer readable medium, and system for content distribution are described. One or more aspects of the method, apparatus, non-transitory computer readable medium, and system include obtaining a prompt describing an element of a content distribution campaign; generating, using a machine learning model, a user journey based on the prompt, wherein the user journey includes at least one touchpoint for the content distribution campaign; and providing digital content to a user corresponding to the at least one touchpoint based on the user journey.

A method, apparatus, non-transitory computer readable medium, and system for content distribution are described. One or more aspects of the method, apparatus, non-transitory computer readable medium, and system include initializing a machine learning model; obtaining training data including user journey data; and training, using the training data, the machine learning model to generate a user journey based on a prompt.

An apparatus and system for content distribution are described. One or more aspects of the apparatus and system include one or more processors; one or more memory components storing instructions executable by the one or more processors; and a machine learning model comprising parameters stored in the one or more memory components and trained to generate a user journey based on a prompt, wherein the user journey includes at least one touchpoint for a content distribution campaign.

### BRIEF DESCRIPTION OF THE DRAWINGS

FIG. 1 shows an example of a content distribution system according to aspects of the present disclosure.

FIG. 2 shows an example of a content distribution apparatus according to aspects of the present disclosure.

FIG. 3 shows an example of a transformer according to aspects of the present disclosure.

FIG. 4 shows an example of data flow in a content distribution system according to aspects of the present disclosure.

FIG. 5 shows an example of a method for content distribution according to aspects of the present disclosure.

FIG. 6 shows an example of a method for providing digital content based on a user journey according to aspects of the present disclosure.

FIG. 7 shows an example of a user interface for generating a user journey according to aspects of the present disclosure.

FIG. 8 shows an example of a user interface for viewing a user journey according to aspects of the present disclosure.

FIG. 9 shows an example of a user interface for simulating a user journey according to aspects of the present disclosure.

FIG. 10 shows an example of a user interface for predicting a performance of a user journey according to aspects of the present disclosure.

FIG. 11 shows an example of a method for training a machine learning model according to aspects of the present disclosure.

### DETAILED DESCRIPTION

In some cases, content is distributed based on meaningful information learned from data processing. Data processing refers to a collection and manipulation of data to produce the meaningful information. Machine learning is an information processing field in which algorithms or models such as artificial neural networks are trained to make predictive outputs in response to input data without being specifically programmed to do so.

Content is often provided according to a user journey, which sets out a plan for distributing content elements according to one or more touchpoints (e.g., a planned distribution of content elements via a particular communication channel at a particular time or after a particular event occurs). However, a process of identifying relevant data for a user journey and then planning the user journey based on the identified data is both time-intensive and labor-intensive.

For example, in some cases, content distribution and user experience strategies are informed by a wide variety of factors, including ever-changing market trends, user preferences, and signals from social, economic, and political landscapes. An ability to quickly and intelligently understand, plan for, and react to such factors greatly assists a content provider in achieving its goals.

At the same time, users are increasingly embracing digital channels to engage with content providers and are demanding that content providers personalize their interactions. Therefore, both users and content providers benefit when an intent, stage, and context of users are understood and a digital experience is tailored for the users. In some cases, a confluence of personalization at scale along with a myriad of macro influences presents an opportunity for a content distribution system for digital user experience management that operates at a granularity of an individual user's journey and sequence of experiences, all while helping a content provider to achieve its goals.

However, producing an effective content distribution campaign by synthesizing external and internal data into actionable opportunities, creating superior campaign components (e.g., content, user journeys, objectives, etc.), and optimizing a content distribution strategy over time is not easily achievable for a content provider team, and added challenges of a demand from content providers for new, fresh, and personalized user experiences and siloed teams balancing various overlapping efforts creates further complication for creating an effective campaign.

For example, in some cases, a superior user journey draws upon vast and disparate external and internal data that individual strategists and analysts are not able to effectively comprehend or synthesize within an allotted time. In some cases, a significant part of an analyst's time is spent on retrieving basic key performance indicator (KPI) questions with little bandwidth for deep analysis, while in some cases, strategists such as campaign owners and managers rely on an ad hoc analysis of internal and external sources from analysts to come to a point solution campaign.

Furthermore, in some cases, a process of conceiving, simulating, executing, and evaluating a user journey is laborious and time-consuming and is constrained both by a number of available team members and an ability to rapidly and effectively respond to quickly moving user preferences. For example, in some cases, a conventional process for creating a user journey includes one or more of determining a campaign objective, a channel for content distribution, a target audience, content to be distributed, and determining touchpoints for the user journey. Additionally, in some cases, an end-to-end user journey creation effort is scattered across different roles, making an ability to quickly and dynamically adjust user journey components based on ever-changing trends a challenge.

For example, in some cases, strategists rely on operations teams, creative teams, and other team members to execute a point solution campaign. During such a process, in some cases, a performance-based adjustment to a user journey for the campaign is time-consuming, as the adjustment demands waiting for a full cycle to re-engage team members that are now occupied with different tasks. Additionally, in some cases, a user journey creation effort is hampered by a lack of healthy knowledge-sharing practices across teams, resulting in silos, inefficiencies, and bottlenecks.

Still further, in some cases, content distribution workflows are heavy, manual, and dependent upon a constant supply of human ingenuity and accuracy. For example, in some cases, operations team members that are focused on building user journeys perform numerous iterations according to an intuition of what aspects of a prospective user journey might be effective. Additionally, in some cases, creative team members have a limited capacity to create variations of content for campaigns, particularly based on historical performance and content affinity variations for clients and consumers. Additionally, in some cases, an ability to create a tailored experience and user journey for each unique user is constrained by an ability of content provider teams to generate and deliver appropriate content at an appropriate time.

According to some aspects, a content distribution system includes a user experience platform and a machine learning model. In some cases, the user experience platform is configured to obtain a prompt describing an element of a content distribution campaign. In some cases, the machine learning model is trained to generate a user journey based on the prompt. In some cases, the user journey includes at least one touchpoint for the content distribution campaign. In some cases, the user experience platform is further configured to provide digital content to the user corresponding to the at least one touchpoint based on the user journey.

Accordingly, by generating the user journey using the machine learning model, the content distribution system avoids a time-consuming and labor-intensive process used by conventional content distribution systems of manually creating a user journey. Furthermore, by providing content to the user corresponding to the touchpoint, the content distribution system is able to provide targeted content to a target user in a more efficient manner than conventional content distribution systems provide.

According to some aspects, the machine learning model is further trained to simulate one or more instances of the user journey and to generate one or more predicted performance values based on the simulation. Accordingly, in some cases, the content distribution system minimizes experimentation and provides an efficient and intuitive ability for a content provider to select a user journey instance that will be effective in achieving an objective of the content provider while avoiding ineffective user journey instances, saving the content provider time, effort, and resources.

A content distribution system according to an aspect of the present disclosure is used in a content distribution campaign context. In an example, a content provider has identified a user segment to be targeted by a content distribution campaign, a content element to be distributed to the user segment during the content distribution campaign, and a program for the content distribution campaign.

In some cases, the content provider provides an input to a user interface of the content distribution system asking the system to provide a user journey for the content distribution campaign. In some cases, in response to the content provider input, a user experience platform of the content distribution system generates a prompt for a machine learning model of the content distribution system. In some cases, the prompt includes the content provider input and context corresponding to the content provider input (such as information for the content distribution campaign, a content provider profile, content provider preferences, a content provider interaction history with the content distribution system, etc.).

In some cases, the machine learning model generates a user journey based on the prompt. In some cases, the content provider input and the context included in the prompt allows the machine learning model to generate a user journey that is responsive to the content provider's objectives and to the elements of the campaign that have been created or generated so far.

In some cases, the machine learning model provides the user journey to the user experience platform. In some cases, the user journey includes instructions or code executable by the user experience platform (such as a macro) to display a representation of the user journey via the user interface.

In some cases, the user experience platform provides content to a user according to a touchpoint of the user journey. In an example, the user experience platform displays an image identified by the user journey to a user in a user segment targeted by the user journey via a promotional website identified by the user journey. In the example, when the user books travel within three days after viewing the image, the content distribution system emails the user a message thanking the user for booking and offering the user a 10% discount on a tour.

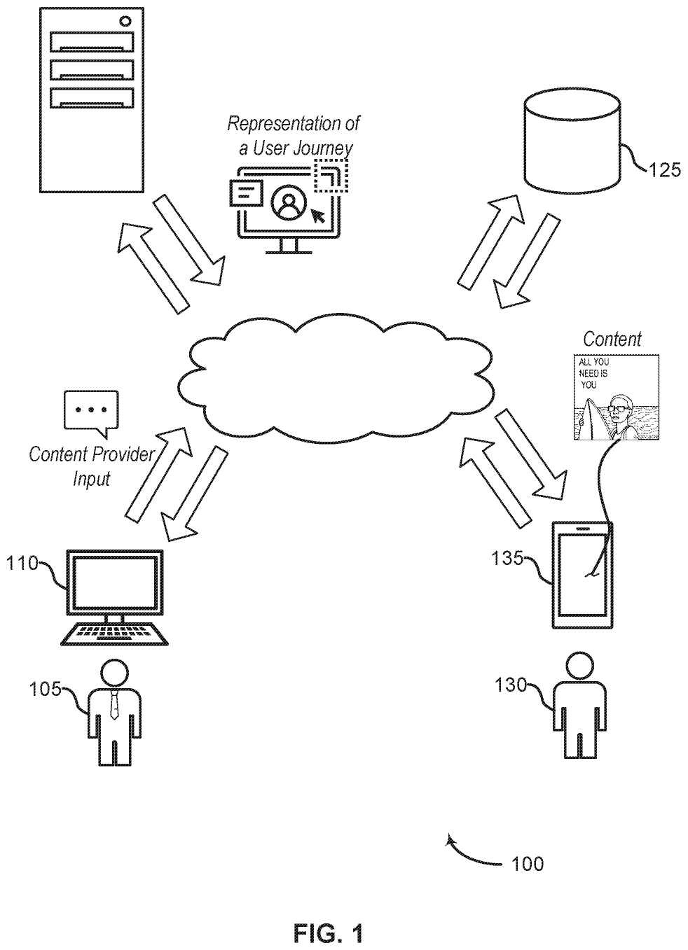

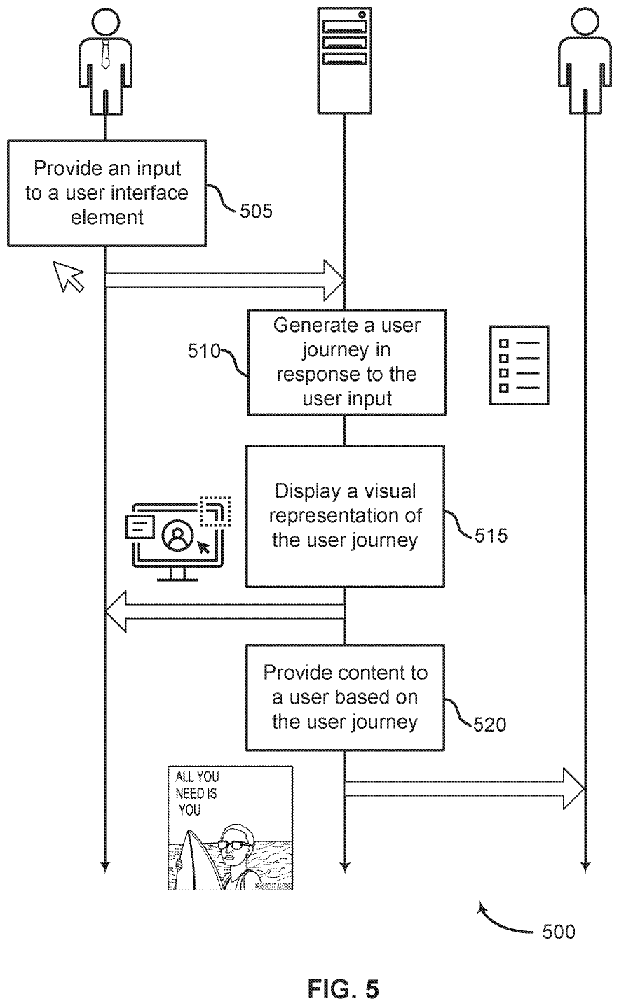

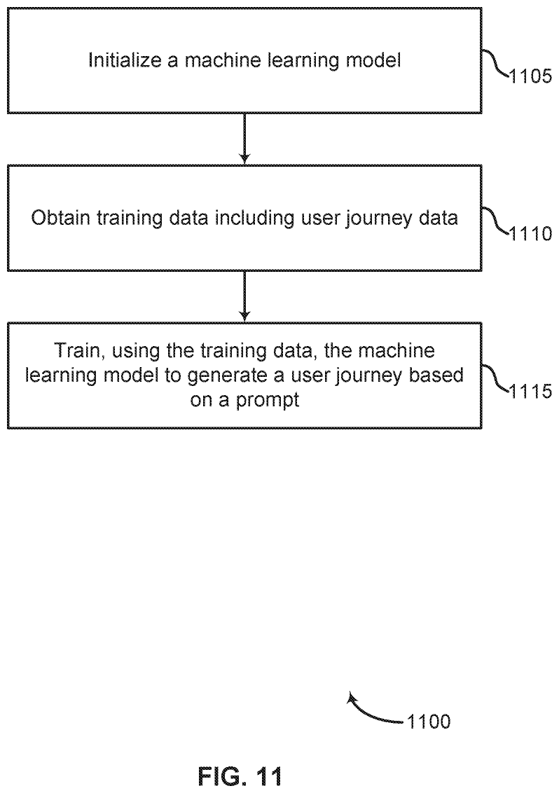

Further example applications of the present disclosure in the content distribution campaign context are provided with reference to FIGS. 1 and 5. Details regarding the architecture of the content distribution system are provided with reference to FIGS. 1-4. Details regarding a process for content distribution are provided with reference to FIGS. 5-10. Details regarding a process for training a machine learning model are provided with reference to FIG. 11.

As used herein, in some cases, a “content provider” refers to a person or entity that interacts with the content distribution system and/or content distribution apparatus. As used herein, in some cases, a “content provider preference” refers to any information provided by the content provider to the content distribution system. In some cases, a content provider preference includes one or more of a preferred content, a preferred communication channel, a preferred campaign objective, a preferred user segment, a preferred time period for content distribution, and any other information that is used in developing a content distribution campaign for a content provider.

As used herein, a “user segment” or “audience” refers to a group of users corresponding to a group of user profiles and identified by a group of user identifiers. As used herein, a “user profile” refers to data corresponding to a user. Examples of data corresponding to a user include a name, contact information, demographic data, user device information, a purchase history, a correspondence history, and any other data relating to the user. As used herein, a “user identifier” refers to a unique identifier (such as a name, an email address, an identification number, etc.) for a user. In some cases, a user profile includes a user identifier. In some cases, the user segment includes one or more users corresponding to user profiles that include a common attribute or quality.

As used herein, a “context” refers to contextual information for a user experience platform. As used herein, a “profile information for a content provider” or a “content provider profile” refers to any available data for a content provider, such as an identifier, a title, a role within an organization, content provider preferences, etc. As used herein, an “interaction history of the content provider” refers to data relating to any interaction of the content provider or a user with the content distribution system, such as inputs provided to the content distribution system, user interfaces viewed by content provider, content provided by the content distribution system for the content provider, time spent interacting with the content distribution system, an active user interface element, a currently selected user interface element, information represented in a user interface element, content received by the user from the content distribution system, information relating to the content received by the user, etc.

In some cases, a context includes one or more of: the profile information for a content provider; the interaction history of the content provider; information corresponding to an active user interface (such as data corresponding to information being represented by the user interface, link selection within the user interface, a mouse or other input position in the user interface, an amount of time spent in the user interface, etc.); an analytics context; an audience segmentation context; a campaign generation context; structured information representing a user journey, a campaign brief, or a campaign program; information in multiple modalities, such as a text modality or an image modality; data corresponding to a data trend or anomaly; an insight; an opportunity; content provider preferences (such as a campaign objective, a campaign goal, a preferred user segment, a preferred communication channel, preferred content, etc.); a content provider playbook; a key performance indicator; previous content provider feedback; historical user journeys; historical user journey simulation results; and any other available information that is or has been presented to or retrieved by the user experience platform.

As used herein, in some cases, a “user experience platform” includes a set of creative, analytics, social, advertising, media optimization, targeting, Web experience management, journey orchestration and content management tools. In some cases, a user experience platform comprises one or more ANNs trained to generate content. In some cases, a user experience platform provides the user interface. In some cases, the user experience platform communicates with a database. In some cases, the user experience platform comprises the database.

As used herein, a “prompt” refers to an input to a machine learning model. In some cases, the prompt includes the context. In some cases, the prompt includes an instruction to generate a user journey based on the context. In some cases, the prompt includes text provided by a content provider. In some cases, the prompt includes an instruction to generate the user journey according to one or more of the context, the text provided by the content provider, and the instruction. In some cases, one or more of the text provided by the content provider and the instruction includes natural language. As used herein, “natural language” refers to any language that has emerged through natural use.

In some cases, the user experience platform generates the prompt. In some cases, the user experience platform generates the prompt in response to a content provider input to an element of a user interface. In some cases, the user experience platform generates the prompt in response to a change in the context. In some cases, the content provider provides the prompt to the machine learning model (for example, via a user interface configured to communicate with the machine learning model).

In some cases, the prompt includes one or more embeddings. As used herein, an “embedding” refers to a mathematical representation of an object (such as text, an image, a chart, audio, etc.) in a lower-dimensional space, such that information about the object is more easily captured and analyzed by a machine learning model. For example, in some cases, an embedding is a numerical representation of the object in a continuous vector space in which objects that have similar semantic information correspond to vectors that are numerically similar to and thus “closer” to each other, providing for an ability of a machine learning model to effectively compare the objects corresponding to the embeddings with each other.

In some cases, an embedding is produced in a “modality” (such as a text modality, a chart modality, an image modality, an audio modality, etc.) that corresponds to a modality of the corresponding object. In some cases, embeddings in different modalities include different dimensions and characteristics, which makes a direct comparison of embeddings from different modalities difficult. In some cases, an embedding for an object is generated or translated into a multimodal embedding space, such that objects from multiple modalities are effectively compared with each other.

As used herein, in some cases, “content” includes any form of media, including goods, services, physically tangible media, and the like, and digital content, including media such as text, audio, images, video, or a combination thereof. In some cases, content includes text, such as descriptions, summaries, insights, opportunities, structured queries, campaign briefs, user journey outlines, copy, subject headlines, hashtags, text for inclusion in an image, etc. In some cases, content includes instructions or code (such as a macro) that is executed by the user experience platform to retrieve and/or generate content, such as an image, a chart, a slide presentation, a video, audio, etc. In some cases, content includes instructions or code that is executed by the user experience platform to display content or a representation of the content via the user interface. As used herein, a “content element” refers to a discrete item of content or a portion of the content.

As used herein, in some cases, an “insight” includes a natural language description of a data trend or anomaly. In some cases, the insight includes a natural language analysis of the data trend (such as an identification of a predicted cause or contributing factor for the data trend and a prediction of an effect of the data trend). In some cases, the insight includes a text instruction provided in an appropriate format (such as an instruction, code, a macro, etc.) for a different component (such as the user experience platform) to take some action (such as retrieve, generate, and or/display content). In some cases, an insight is synthesized and curated from external and internal sources in various forms, such as data stories, charts, visuals, etc.

In some cases, the data sources are inclusive of at least one of a foundational enterprise/content distribution focus and a unique content provider-specific foundation. Examples of data having a foundational enterprise/content distribution focus include publicly available competitor information and announcements, market research reports, brand awareness and perception data, company and industry data, demographic data, seasonal data, macroeconomic data, microeconomic data, and data relating to world events.

Examples of data having a content provider-specific foundation include user and segmentation data, content affinity data based on historical responses to content distribution campaigns, user journey preferences (such as frequency, channels, and content preferences) based on historical performance of content distribution campaigns, share partner or purchased data, historical content distribution campaign details and performance data, brand guidelines and historical content experiences, previous experiments and results, and user research, such as market research and churn analysis.

As used herein, in some cases, an “opportunity” includes a natural language description of an action for the content provider to take based on the insight. In some cases, the opportunity includes a natural language suggestion to the content provider to instruct the content distribution system to take a further action (such as identifying a group of content providers, generating a content distribution campaign, etc.) based on the insight. In some cases, the opportunity includes a text instruction provided in an appropriate format (such as a programming language) for a different component (such as the user experience platform) to take an action (such as identifying the group of content providers, generating the content distribution campaign, etc.). In some cases, an opportunity is curated with consideration to one or more of a content provider's goals, playbook, active or previous campaigns, and historical performance.

As used herein, in some cases, a “user journey” refers to a description of a plan for providing content to one or more users identified by the user journey during a content distribution campaign. As used herein, in some cases, a “touchpoint” refers to an interaction with a user. In some cases, the user journey includes a set of planned touchpoints in which content is provided to the user. In some cases, a touchpoint of the set of planned touchpoints is planned according to one or more of a period of time, an interaction of the user with a content channel (such as a visit to a physical location or a digital content channel such as a social media feed), or an occurrence of a previous touchpoint. In some cases, a user journey includes a text description identifying one or more of a user segment, a content distribution channel, a content element, and a touchpoint. In some cases, a user journey includes instructions or code executable by a user experience platform (such as a macro) for generating a representation of the user journey (such as a graph). In some cases, the user journey includes instructions for displaying the representation of the user journey via a user interface.

As used herein, a “content distribution campaign”, “communication campaign”, or “campaign” refers to a coordinated distribution of content through one or more content channels in order to achieve one or more goals, such as a number of product purchases, a number of content views, a number of sign-ups, etc. As used herein, an “element of a content distribution campaign” refers to any information included in or associated with a content distribution campaign (e.g., an identification of a user segment, a communication channel, a campaign objective, a content element, etc.).

In some cases, a content distribution campaign is planned according to a campaign brief. As used herein, a “campaign brief” refers to text including a description of one or more components or elements of a content distribution campaign, such as an identification of one or more of content to be distributed, an identification of a user segment for receiving the distributed content, a channel for distributing the content through, and a period (either stage-based or calendar-based) for distributing the content. As used herein, “stage-based” refers to periods determined according to an order of occurrence. As used herein, “calendar-based” refers to periods determined according to calendar dates.

In some cases, a campaign brief defines aspects of a campaign, including one or more of a target audience, a key performance indicator (KPI), an objective for the campaign, a timeframe for providing content according to the campaign, personnel assignments, campaign budget information, and content associated with the campaign. In some cases, the campaign brief is a roadmap for a content provider to execute on and a source of truth for the campaign.

In some cases, the campaign brief identifies a plurality of stages and a program for each of the set of periods. As used herein, in some cases, a “program” refers to a plotted timeline of content distribution according to the set of periods. In some cases, the communication channel is associated with the program for at least one of the set of periods.

In some cases, a content distribution campaign package includes one or more of a campaign brief, a user segment, a generated content experience, the user journey, a simulation of the user journey, and a prediction of a result of the user journey. In some cases, the campaign brief is generated based on one or more of the content provider's goals, a playbook, active or previous campaigns, and a historical performance. In some cases, a user segment is generated based on one or more of a campaign focus, a campaign goal, a historical affinity, and a historical performance.

In some cases, a content experience is generated based on a composition of individual content pieces, such as images, copy, video, audio, subject headlines, hashtags, etc. In some cases, a user journey is generated, simulated, and/or predicted based on one or more of a historical user journey, results of a historical user journey, and industry standards derived from external data.

In some cases, the content distribution campaign package is dynamically optimized and adjusted based on generated insights of emerging external or internal trends. In some cases, the content distribution campaign package is dynamically optimized and adjusted based on feedback loops from the content distribution campaign, where the feedback is provided by one or more of the content provider and a user targeted by the content distribution campaign.

As used herein, a “communication channel” or a “content distribution channel” refers to a physical channel (such as a mailing service, a physical location such as a store, a hotel, an amusement park, etc., and the like) or a digital channel (such as a website, a software application, an Internet-based application, an email service, a messaging service such as SMS, instant messaging, etc., a television service, a telephone service, etc.) through which content or digital content is provided. As used herein, “customized content” refers to content that is customized according to data associated with a content provider or a user.

As used herein, in some cases, a “project” refers to a process of using the content distribution system to produce an output or outcome.

According to some aspects, the content distribution system assists with an ideation, definition, expansion, and refinement of an audience for the content distribution campaign. For example, in some cases, the machine learning model qualifies and quantifies the audience using summary statistics and described traits of the audience along with projected performance of the audience towards the content distribution objective of the content provider.

According to some aspects, the content distribution system employs at least one of the user experience platform and the machine learning model to generate a complete content distribution campaign, including a program, messaging, content, and journey, or a combination thereof. For example, in some cases, the content distribution system optimizes the content distribution campaign for a target audience to meet the content distribution objective of the content provider.

According to some aspects, the content distribution system infuses capabilities of the machine learning model with capabilities of the user experience cloud to provide a multimodal conversational interface capable of brainstorming, ideation, and reasoning, that retains and adapts to context. In some cases, the conversational interface is implemented as a copilot for user experience management.

According to some aspects, the content distribution system is directed by feedback (such as additional inputs and/or dimensions) to dynamically and continuously regenerate generated outputs. According to some aspects, journeys, journey simulation, and performance predictions are based on historical journey data of a content provider combined with external journey data leveraged by the machine learning model.

Accordingly, in some cases, the content distribution system provides a content provider with efficiency, efficacy, scale, agility, velocity, ideation, collaboration, and/or execution, thereby allowing the content provider to do more with less.

### Content Distribution

A system and an apparatus for content distribution are described with reference to FIGS. 1-4. One or more aspects of the system and the apparatus include one or more processors; one or more memory components storing instructions executable by the one or more processors; and a machine learning model comprising parameters stored in the one or more memory components and trained to generate a user journey based on a prompt, wherein the user journey includes at least one touchpoint for a content distribution campaign.

In some aspects, the machine learning model comprises a transformer architecture. In some aspects, the machine learning model comprises a large language model. In some aspects, the machine learning model is further trained to simulate one or more instances of the user journey and to generate one or more predicted performance values based on the simulation.

Some examples of the system and the apparatus further include a user experience platform configured to generate digital content corresponding to the at least one touchpoint based on the user journey. Some examples of the system and the apparatus further include a user interface configured to display a graph representing the user journey including a node corresponding to the at least one touchpoint. Some examples of the system and the apparatus further include a training component configured to train the machine learning model to generate a user journey.

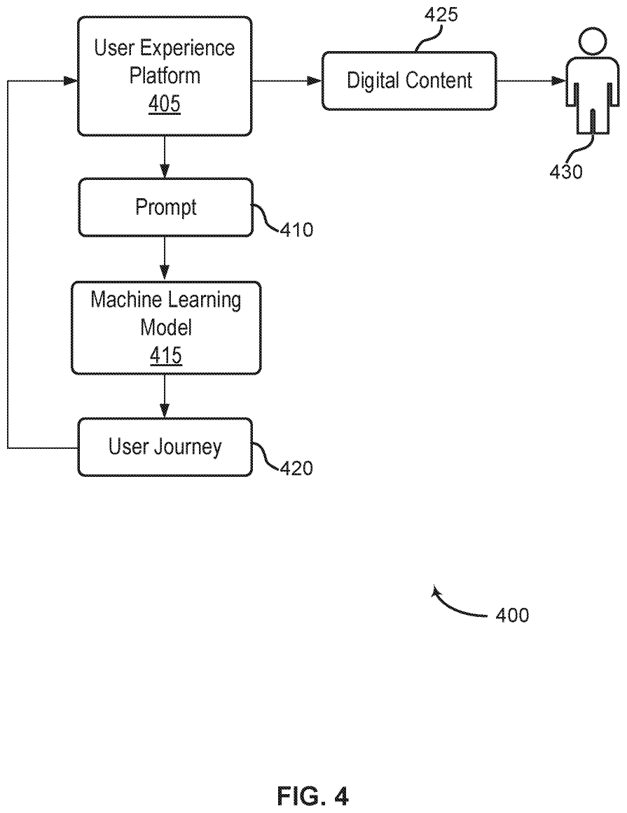

FIG. 1 shows an example of a content distribution system 100 according to aspects of the present disclosure. The example shown includes content provider 105, content provider device 110, content distribution apparatus 115, cloud 120, database 125, user 130, and user device 135. Content distribution system 100 is an example of, or includes aspects of, the corresponding element described with reference to FIG. 4.

Referring to FIG. 1, according to some aspects, content provider 105 provides an input to content distribution apparatus 115 (e.g., via a user interface provided on content provider device 110 by content distribution apparatus 115) instructing content distribution apparatus 115 to provide a user journey. In some cases, content distribution apparatus 115 generates a user journey based on a prompt in response to the content provider input. In some cases, content distribution apparatus 115 displays a representation of the user journey to content provider 105 via the user interface. In some cases, content distribution apparatus 115 provides content to user 130 via user device 135 according to a touchpoint of the user journey.

Content provider device 110 is an example of, or includes aspects of, the corresponding element described with reference to FIG. 4. According to some aspects, content provider device 110 is a personal computer, laptop computer, mainframe computer, palmtop computer, personal assistant, mobile device, or any other suitable processing apparatus. In some examples, content provider device 110 includes software that displays the user interface (e.g., the graphical user interface) provided by content distribution apparatus 115. In some aspects, the user interface allows information (such as text, an image, etc.) to be communicated between content provider 105 and content distribution apparatus 115.

According to some aspects, a content provider device user interface enables content provider 105 to interact with content provider device 110. In some embodiments, the content provider device user interface includes an audio device, such as an external speaker system, an external display device such as a display screen, or an input device (e.g., a remote-control device interfaced with the user interface directly or through an I/O controller module). In some cases, the content provider device user interface is a graphical user interface.

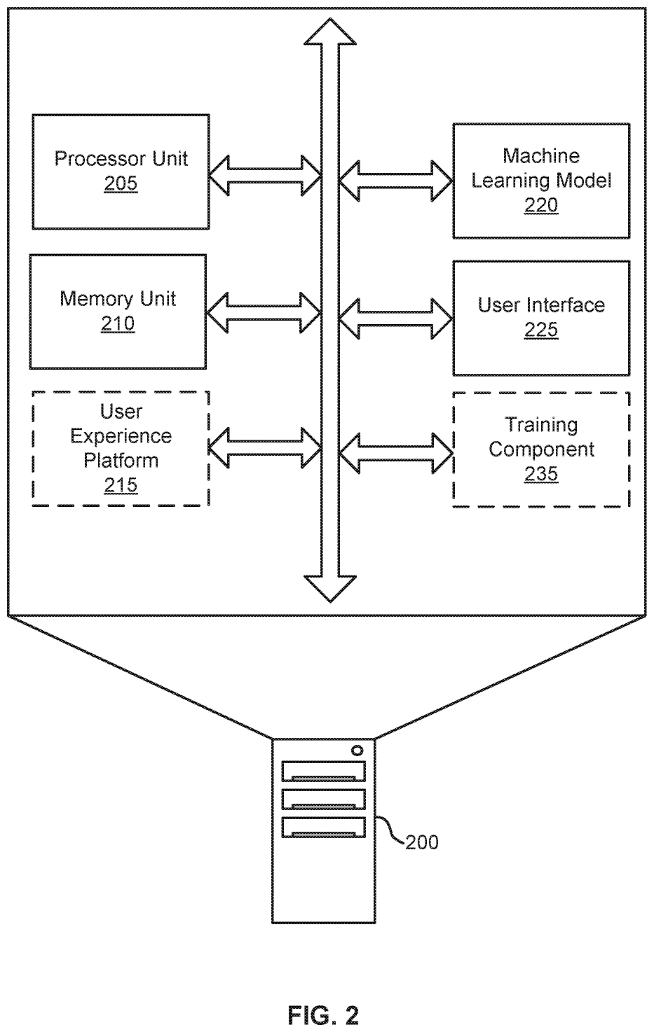

Content distribution apparatus 115 is an example of, or includes aspects of, the corresponding element described with reference to FIG. 2. According to some aspects, content distribution apparatus 115 includes a computer-implemented network. In some embodiments, the computer-implemented network includes a machine learning model (such as the machine learning model described with reference to FIGS. 2 and 4). In some embodiments, content distribution apparatus 115 also includes one or more processors, a memory subsystem, a communication interface, an I/O interface, one or more user interface components, and a bus. Additionally, in some embodiments, content distribution apparatus 115 communicates with content provider device 110 and database 125 via cloud 120.

In some cases, content distribution apparatus 115 is implemented on a server. A server provides one or more functions to content providers linked by way of one or more of various networks, such as cloud 120. In some cases, the server includes a single microprocessor board, which includes a microprocessor responsible for controlling all aspects of the server. In some cases, the server uses microprocessor and protocols to exchange data with other devices or content providers on one or more of the networks via one or more of hypertext transfer protocol (HTTP), simple mail transfer protocol (SMTP), file transfer protocol (FTP), and simple network management protocol (SNMP). In some cases, the server is configured to send and receive hypertext markup language (HTML) formatted files (e.g., for displaying web pages). In various embodiments, the server comprises a general-purpose computing device, a personal computer, a laptop computer, a mainframe computer, a supercomputer, or any other suitable processing apparatus.

Further detail regarding the architecture of content distribution apparatus 115 is provided with reference to FIGS. 2-4. Further detail regarding a process for content distribution is provided with reference to FIGS. 5-10. Further detail regarding a process for training a machine learning model is provided with reference to FIG. 11.

Cloud 120 is a computer network configured to provide on-demand availability of computer system resources, such as data storage and computing power. In some examples, cloud 120 provides resources without active management by a content provider. The term “cloud” is sometimes used to describe data centers available to many content providers over the Internet.

Some large cloud networks have functions distributed over multiple locations from central servers. A server is designated an edge server if it has a direct or close connection to a content provider. In some cases, cloud 120 is limited to a single organization. In other examples, cloud 120 is available to many organizations.

In one example, cloud 120 includes a multi-layer communications network comprising multiple edge routers and core routers. In another example, cloud 120 is based on a local collection of switches in a single physical location. According to some aspects, cloud 120 provides communications between content provider device 110, content distribution apparatus 115, database 125, and user device 135.

Database 125 is an organized collection of data. In an example, database 125 stores data in a specified format known as a schema. According to some aspects, database 125 is structured as a single database, a distributed database, multiple distributed databases, or an emergency backup database. In some cases, a database controller manages data storage and processing in database 125 via a manual interaction or automatically. According to some aspects, database 125 is external to content distribution apparatus 115 and communicates with content distribution apparatus 115 via cloud 120. According to some aspects, database 125 is included in content distribution apparatus 115. According to some aspects, database 125 stores a context. According to some aspects, database 125 stores at least some of the context.

User device 135 is an example of, or includes aspects of, the corresponding element described with reference to FIG. 4. According to some aspects, user device 135 is a personal computer, laptop computer, mainframe computer, palmtop computer, personal assistant, mobile device, or any other suitable processing apparatus. In some aspects, a user interface provided on user device 135 (for example, by content distribution apparatus 115 or an external system in communication with content distribution apparatus 115) allows content to be communicated by content distribution apparatus 115 to user 130.

According to some aspects, a user device user interface enables user 130 to interact with user device 135. In some embodiments, the user device user interface includes an audio device, such as an external speaker system, an external display device such as a display screen, or an input device (e.g., a remote-control device interfaced with the user interface directly or through an I/O controller module). In some cases, the user device user interface is a graphical user interface.

FIG. 2 shows an example of a content distribution apparatus 200 according to aspects of the present disclosure. Content distribution apparatus 200 is an example of, or includes aspects of, the corresponding element described with reference to FIG. 1. In one aspect, content distribution apparatus 200 includes processor unit 205, memory unit 210, user experience platform 215, machine learning model 220, user interface 225, and training component 230.

Processor unit 205 includes one or more processors. A processor is an intelligent hardware device, such as a general-purpose processing component, a digital signal processor (DSP), a central processing unit (CPU), a graphics processing unit (GPU), a microcontroller, an application specific integrated circuit (ASIC), a field programmable gate array (FPGA), a programmable logic device, a discrete gate or transistor logic component, a discrete hardware component, or any combination thereof.

In some cases, processor unit 205 is configured to operate a memory array using a memory controller. In other cases, a memory controller is integrated into processor unit 205. In some cases, processor unit 205 is configured to execute computer-readable instructions stored in memory unit 210 to perform various functions. In some aspects, processor unit 205 includes special purpose components for modem processing, baseband processing, digital signal processing, or transmission processing.

Memory unit 210 includes one or more memory devices. Examples of a memory device include random access memory (RAM), read-only memory (ROM), or a hard disk. Examples of memory devices include solid state memory and a hard disk drive. In some examples, memory is used to store computer-readable, computer-executable software including instructions that, when executed, cause at least one processor of processor unit 205 to perform various functions described herein.

In some cases, memory unit 210 includes a basic input/output system (BIOS) that controls basic hardware or software operations, such as an interaction with peripheral components or devices. In some cases, memory unit 210 includes a memory controller that operates memory cells of memory unit 210. For example, in some cases, the memory controller includes a row decoder, column decoder, or both. In some cases, memory cells within memory unit 210 store information in the form of a logical state.

User experience platform 215 is an example of, or includes aspects of, the corresponding element described with reference to FIG. 4. According to some aspects, user experience platform 215 is implemented as software stored in memory unit 210 and executable by processor unit 205, as firmware, as one or more hardware circuits, or as a combination thereof.

According to some aspects, user experience platform 215 is omitted from content distribution apparatus 200 and is implemented in at least one apparatus separate from content distribution apparatus 200 (for example, at least one apparatus comprised in a cloud, such as the cloud described with reference to FIG. 1). According to some aspects, the separate apparatus comprising user experience platform 215 communicates with content distribution apparatus 200 (for example, via the cloud) to perform the functions of user experience platform 215 described herein.

For example, in some cases, content distribution apparatus 200 is implemented as an edge server in a content distribution system (such as the content distribution system described with reference to FIGS. 1 and 4), user experience platform 215 is included in a central server of the content distribution system, and content distribution apparatus 200 communicates with the central server to implement the functions of user experience platform 215 described herein.

According to some aspects, user experience platform 215 includes a set of creative, analytics, social, advertising, media optimization, targeting, Web experience management, journey orchestration and content management tools. In some cases, user experience platform 215 includes one or more of a graphic design component providing image generation and/or editing capabilities, a video editing component, a web development component, and a photography component.

In some cases, user experience platform 215 comprises one or more of an enterprise content management component; a digital asset management component; an enterprise content distribution component that manages direct content distribution campaigns, leads, resources, user data, and analytics, and allows content providers to design and orchestrate targeted and personalized campaigns via channels such as direct mail, e-mail, SMS, and MMS; a data management component for data modeling and predictive analytics; and a web analytics system that provides web metrics, dimensions, and allows content provider to define tags implemented in webpage for web tracking to provide customized dimensions, metrics, segmentations, content provider reports, and dashboards.

In some cases, user experience platform 215 has comprehensive end-to-end capabilities with content distribution-specific technology across conceptualization, execution, and insights to merge with machine learning model 220 and generative machine learning experiences. In some cases, user experience platform 215 builds a cohesive user view, supporting but not limited to analytics, digital advertising, email, user data management, social media, call centers, and commerce. In some cases, user experience platform 215 consolidates, identifies, and builds full profiles from datasets that provide differentiating data for generating content that benefits from personalization.

According to some aspects, user experience platform 215 comprises one or more artificial neural networks (ANNs), and one or more components of user experience platform 215 are implemented via the one or more ANNs. In some cases, user experience platform 215 comprises one or more generative machine learning models configured to generate content.

An ANN is a hardware component or a software component that includes a number of connected nodes (i.e., artificial neurons) that loosely correspond to the neurons in a human brain. Each connection, or edge, transmits a signal from one node to another (like the physical synapses in a brain). When a node receives a signal, it processes the signal and then transmits the processed signal to other connected nodes.

In some cases, the signals between nodes comprise real numbers, and the output of each node is computed by a function of the sum of its inputs. In some examples, nodes determine their output using other mathematical algorithms, such as selecting the max from the inputs as the output, or any other suitable algorithm for activating the node. Each node and edge are associated with one or more node weights that determine how the signal is processed and transmitted.

In ANNs, a hidden (or intermediate) layer includes hidden nodes and is located between an input layer and an output layer. Hidden layers perform nonlinear transformations of inputs entered into the network. Each hidden layer is trained to produce a defined output that contributes to a joint output of the output layer of the ANN. Hidden representations are machine-readable data representations of an input that are learned from hidden layers of the ANN and are produced by the output layer. As the understanding of the ANN of the input improves as the ANN is trained, the hidden representation is progressively differentiated from earlier iterations.

During a training process of an ANN, the node weights are adjusted to improve the accuracy of the result (i.e., by minimizing a loss which corresponds in some way to the difference between the current result and the target result). The weight of an edge increases or decreases the strength of the signal transmitted between nodes. In some cases, nodes have a threshold below which a signal is not transmitted at all. In some examples, the nodes are aggregated into layers. Different layers perform different transformations on their inputs. The initial layer is known as the input layer and the last layer is known as the output layer. In some cases, signals traverse certain layers multiple times.

According to some aspects, user experience platform 215 obtains a prompt for machine learning model 220. In some examples, user experience platform 215 obtains a prompt describing an element of a content distribution campaign. In some examples, user experience platform 215 provides digital content to a user corresponding to the at least one touchpoint based on the user journey.

Machine learning model 220 is an example of, or includes aspects of, the corresponding element described with reference to FIG. 4. According to some aspects, machine learning model 220 is implemented as software stored in memory unit 210 and executable by processor unit 205, as firmware, as one or more hardware circuits, or as a combination thereof. In some cases, machine learning model 220 is included in user experience platform 215. According to some aspects, machine learning model 220 comprises one or more ANNs designed and/or trained to generate content based on a prompt.

According to some aspects, machine learning model 220 includes machine learning parameters stored in memory unit 210. Machine learning parameters are variables that provide a behavior and characteristics of a machine learning model. In some cases, machine learning parameters are learned or estimated from training data and are used to make predictions or perform tasks based on learned patterns and relationships in the data.

In some cases, machine learning parameters are adjusted during a training process to minimize a loss function or to maximize a performance metric. The goal of the training process is to find optimal values for the parameters that allow the machine learning model to make accurate predictions or perform well on a given task.

For example, during the training process, an algorithm adjusts machine learning parameters to minimize an error or loss between predicted outputs and actual targets according to optimization techniques like gradient descent, stochastic gradient descent, or other optimization algorithms. Once the machine learning parameters are learned from the training data, the machine learning parameters are used to make predictions on new, unseen data.

In some cases, parameters of an ANN include weights and biases associated with each neuron in the ANN that control a strength of connections between neurons and influence the ability of the ANN to capture complex patterns in data.

According to some aspects, machine learning model 220 comprises a large language model. A large language model is machine learning model that is designed and/or trained to learn statistical patterns and structures of human language. Large language models are capable of a wide range of language-related tasks such as text completion, question answering, translation, summarization, and creative writing, in response to a prompt. In some cases, the term “large” refers to a size and complexity of the large language model, usually measured in terms of a number of parameters of the large language model, where more parameters allow a large language model to understand more intricate language patterns and generate more nuanced and coherent text.

In some cases, the large language model comprises a sequence-to-sequence (seq2seq) model. A seq2seq model comprises one or more ANNs configured to transform a given sequence of elements, such as a sequence of words in a sentence, into another sequence using sequence transformation.

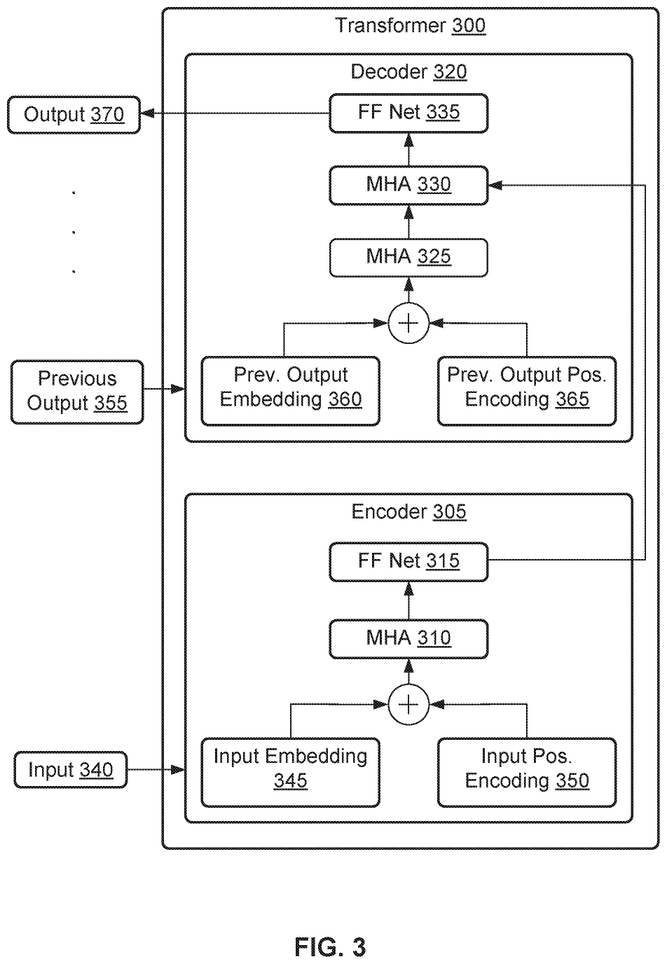

In some cases, machine learning model 220 comprises one or more transformers (such as the transformer described with reference to FIG. 3). In some cases, a transformer comprises one or more ANNs comprising attention mechanisms that enable the transformer to weigh an importance of different words or tokens within a sequence. In some cases, a transformer processes entire sequences simultaneously in parallel, making the transformer highly efficient and allowing the transformer to capture long-range dependencies more effectively.

In some cases, a transformer comprises an encoder-decoder structure. In some cases, the encoder of the transformer processes an input sequence and encodes the input sequence into a set of high-dimensional representations. In some cases, the decoder of the transformer generates an output sequence based on the encoded representations and previously generated tokens. In some cases, the encoder and the decoder are composed of multiple layers of self-attention mechanisms and feed-forward ANNs.

In some cases, the self-attention mechanism allows the transformer to focus on different parts of an input sequence while computing representations for the input sequence. In some cases, the self-attention mechanism captures relationships between words of a sequence by assigning attention weights to each word based on a relevance to other words in the sequence, thereby enabling the transformer to model dependencies regardless of a distance between words.

An attention mechanism is a key component in some ANN architectures, particularly ANNs employed in natural language processing (NLP) and sequence-to-sequence tasks, that allows an ANN to focus on different parts of an input sequence when making predictions or generating output.

NLP refers to techniques for using computers to interpret or generate natural language. In some cases, NLP tasks involve assigning annotation data such as grammatical information to words or phrases within a natural language expression. Different classes of machine-learning algorithms have been applied to NLP tasks. Some algorithms, such as decision trees, utilize hard if-then rules. Other systems use neural networks or statistical models which make soft, probabilistic decisions based on attaching real-valued weights to input features. In some cases, these models express the relative probability of multiple answers.

Some sequence models (such as recurrent neural networks) process an input sequence sequentially, maintaining an internal hidden state that captures information from previous steps. However, in some cases, this sequential processing leads to difficulties in capturing long-range dependencies or attending to specific parts of the input sequence.

The attention mechanism addresses these difficulties by enabling an ANN to selectively focus on different parts of an input sequence, assigning varying degrees of importance or attention to each part. The attention mechanism achieves the selective focus by considering a relevance of each input element with respect to a current state of the ANN.

In some cases, an ANN employing an attention mechanism receives an input sequence and maintains its current state, which represents an understanding or context. For each element in the input sequence, the attention mechanism computes an attention score that indicates the importance or relevance of that element given the current state. The attention scores are transformed into attention weights through a normalization process, such as applying a softmax function. The attention weights represent the contribution of each input element to the overall attention. The attention weights are used to compute a weighted sum of the input elements, resulting in a context vector. The context vector represents the attended information or the part of the input sequence that the ANN considers most relevant for the current step. The context vector is combined with the current state of the ANN, providing additional information and influencing subsequent predictions or decisions of the ANN.

In some cases, by incorporating an attention mechanism, an ANN dynamically allocates attention to different parts of the input sequence, allowing the ANN to focus on relevant information and capture dependencies across longer distances.

In some cases, calculating attention involves three basic steps. First, a similarity between a query vector Q and a key vector K obtained from the input is computed to generate attention weights. In some cases, similarity functions used for this process include dot product, splice, detector, and the like. Next, a softmax function is used to normalize the attention weights. Finally, the attention weights are weighed together with their corresponding values V. In the context of an attention network, the key K and value V are typically vectors or matrices that are used to represent the input data. The key K is used to determine which parts of the input the attention mechanism should focus on, while the value V is used to represent the actual data being processed.

According to some aspects, machine learning model 220 generates a user journey based on the prompt, where the user journey includes at least one touchpoint for the content distribution campaign. In some aspects, the user journey includes a set of touchpoints connected by a set of edges. In some aspects, each of the set of touchpoints corresponds to a stage of the content distribution campaign. In some examples, generating the user journey includes encoding the prompt to obtain a sequence of input tokens and generating a sequence of output tokens based on the sequence of input tokens, where the user journey is based on the sequence of output tokens.

In some aspects, the machine learning model 220 is trained using training data including a set of user journeys. According to some aspects, machine learning model 220 generates a predicted touchpoint.

In some examples, machine learning model 220 simulates one or more instances of the user journey. In some examples, machine learning model 220 identifies a user journey path, where the simulation is based on the user journey path. In some aspects, the simulation is based on one or more user attributes. In some examples, machine learning model 220 generates one or more predicted performance values based on the simulation. In some examples, machine learning model 220 updates the simulation based on the one or more predicted performance values.

According to some aspects, machine learning model 220 is trained to generate a user journey based on a prompt, wherein the user journey includes at least one touchpoint for a content distribution campaign. In some aspects, machine learning model 220 is further trained to simulate one or more instances of the user journey and to generate one or more predicted performance values based on the simulation.

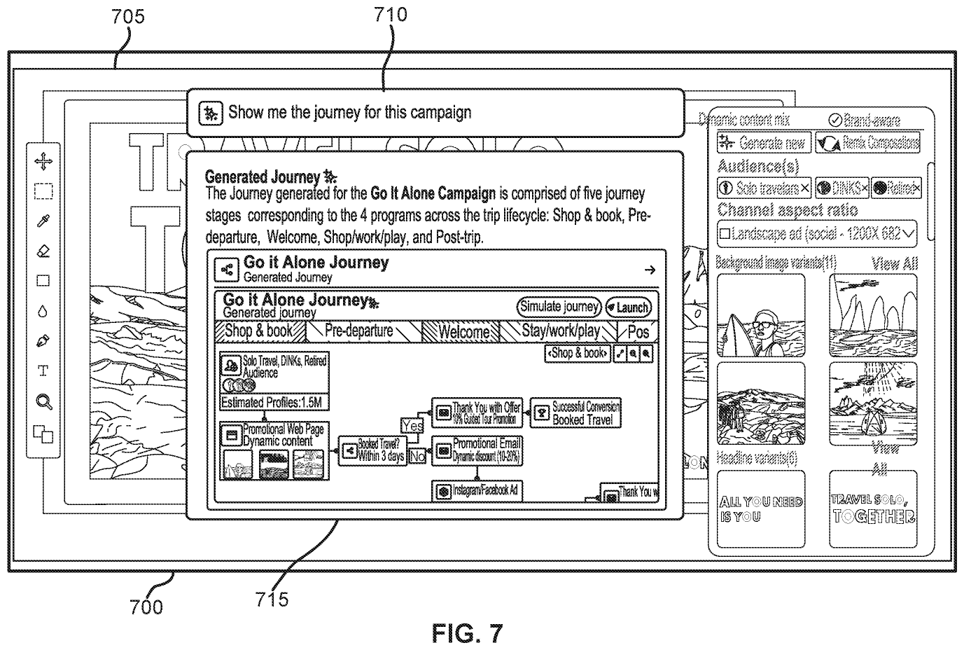

User interface 225 is an example of, or includes aspects of, the corresponding element described with reference to FIGS. 7-10. According to some aspects, user interface 225 provides for communication between a content provider device (such as the content provider device described with reference to FIG. 1) and content distribution apparatus 200. For example, in some cases, user interface 225 is a graphical user interface (GUI) provided on the content provider device by content distribution apparatus 200. According to some aspects, user interface 225 displays a graph representing the user journey including a node corresponding to the at least one touchpoint.

According to some aspects, training component 235 is implemented as software stored in memory unit 210 and executable by processor unit 205, as firmware, as one or more hardware circuits, or as a combination thereof. According to some aspects, training component 235 is omitted from content distribution apparatus 200 and is implemented in at least one apparatus separate from content distribution apparatus 200 (for example, at least one apparatus comprised in a cloud, such as the cloud described with reference to FIG. 1). According to some aspects, the separate apparatus comprising training component 235 communicates with content distribution apparatus 200 (for example, via the cloud) to perform the functions of training component 235 described herein.

According to some aspects, training component 230 initializes machine learning model 220. In some examples, training component 230 obtains training data including user journey data. In some examples, training component 230 trains, using the training data, machine learning model 220 to generate a user journey (for example, based on a prompt).

In some examples, initializing the machine learning model 220 includes obtaining a pre-trained machine learning model. In some examples, training machine learning model 220 includes fine-tuning the pre-trained machine learning model. In some examples, training component 230 compares the predicted touchpoint to a ground-truth touchpoint of the user journey data. In some examples, training component 230 computes a loss function based on the comparison, where the training is based on the loss function.

FIG. 3 shows an example of a transformer 300 according to aspects of the present disclosure. The example shown includes transformer 300, encoder 305, decoder 320, input 340, input embedding 345, input positional encoding 350, previous output 355, previous output embedding 360, previous output positional encoding 365, and output 370.

In some cases, encoder 305 includes multi-head self-attention sublayer 310 and feed-forward network sublayer 315. In some cases, decoder 320 includes first multi-head self-attention sublayer 325, second multi-head self-attention sublayer 330, and feed-forward network sublayer 335.

According to some aspects, a machine learning model (such as the machine learning model described with reference to FIGS. 2 and 4) comprises transformer 300. In some cases, encoder 305 is configured to map input 340 (for example, a sequence of words or tokens, such as a prompt described herein) to a sequence of continuous representations that are fed into decoder 320. In some cases, decoder 320 generates output 370 (e.g., a predicted sequence of words or tokens) based on the output of encoder 305 and previous output 355 (e.g., a previously predicted output sequence), which allows for the use of autoregression.

For example, in some cases, encoder 305 parses input 340 into tokens and vectorizes the parsed tokens to obtain input embedding 345, and adds input positional encoding 350 (e.g., positional encoding vectors for input 340 of a same dimension as input embedding 345) to input embedding 345. In some cases, input positional encoding 350 includes information about relative positions of words or tokens in input 340.

In some cases, encoder 305 comprises one or more encoding layers (e.g., six encoding layers) that generate contextualized token representations, where each representation corresponds to a token that combines information from other input tokens via self-attention mechanism. In some cases, each encoding layer of encoder 305 comprises a multi-head self-attention sublayer (e.g., multi-head self-attention sublayer 310). In some cases, the multi-head self-attention sublayer implements a multi-head self-attention mechanism that receives different linearly projected versions of queries, keys, and values to produce outputs in parallel. In some cases, each encoding layer of encoder 305 also includes a fully connected feed-forward network sublayer (e.g., feed-forward network sublayer 315) comprising two linear transformations surrounding a Rectified Linear Unit (ReLU) activation:

$$FFN ( x ) = R e L U ( {W}_{1} x + {b}_{1} ) {W}_{2} + {b}_{2} \qquad ( 1 )$$

In some cases, each layer employs different weight parameters (W₁, W₂) and different bias parameters (b₁, b₂) to apply a same linear transformation each word or token in input 340.

In some cases, each sublayer of encoder 305 is followed by a normalization layer that normalizes a sum computed between a sublayer input x and an output sublayer (x) generated by the sublayer:

$$layer norm ( x + sublayer ( x ) ) \qquad ( 2 )$$

In some cases, encoder 305 is bidirectional because encoder 305 attends to each word or token in input 340 regardless of a position of the word or token in input 340.

In some cases, decoder 320 comprises one or more decoding layers (e.g., six decoding layers). In some cases, each decoding layer comprises three sublayers including a first multi-head self-attention sublayer (e.g., first multi-head self-attention sublayer 325), a second multi-head self-attention sublayer (e.g., second multi-head self-attention sublayer 330), and a feed-forward network sublayer (e.g., feed-forward network sublayer 335). In some cases, each sublayer of decoder 320 is followed by a normalization layer that normalizes a sum computed between a sublayer input x and an output sublayer (x) generated by the sublayer.

In some cases, decoder 320 generates previous output embedding 360 of previous output 355 and adds previous output positional encoding 365 (e.g., position information for words or tokens in previous output 355) to previous output embedding 360. In some cases, each first multi-head self-attention sublayer receives the combination of previous output embedding 360 and previous output positional encoding 365 and applies a multi-head self-attention mechanism to the combination. In some cases, for each word in an input sequence, each first multi-head self-attention sublayer of decoder 320 attends only to words preceding the word in the sequence, and so transformer 300's prediction for a word at a particular position only depends on known outputs for a word that came before the word in the sequence. For example, in some cases, each first multi-head self-attention sublayer implements multiple single-attention functions in parallel by introducing a mask over values produced by the scaled multiplication of matrices Q and K by suppressing matrix values that would otherwise correspond to disallowed connections.

In some cases, each second multi-head self-attention sublayer implements a multi-head self-attention mechanism similar to the multi-head self-attention mechanism implemented in each multi-head self-attention sublayer of encoder 305 by receiving a query Q from a previous sublayer of decoder 320 and a key K and a value V from the output of encoder 305, allowing decoder 320 to attend to each word in the input 340.

In some cases, each feed-forward network sublayer implements a fully connected feed-forward network similar to feed-forward network sublayer 315. In some cases, the feed-forward network sublayers are followed by a linear transformation and a softmax to generate a prediction of output 370 (e.g., a prediction of a next word or token in a sequence of words or tokens). Accordingly, in some cases, transformer 300 generates and/or simulates a user journey as described herein based on a predicted sequence of words or tokens.

FIG. 4 shows an example of data flow in a content distribution system 400 according to aspects of the present disclosure. The example shown includes user experience platform 405, prompt 410, machine learning model 415, user journey 420, digital content 425, and user 430.

Content distribution system 400 is an example of, or includes aspects of, the corresponding element described with reference to FIG. 1. User experience platform 405 is an example of, or includes aspects of, the corresponding element described with reference to FIG. 2. Machine learning model 415 is an example of, or includes aspects of, the corresponding element described with reference to FIG. 2. User 430 is an example of, or includes aspects of, the corresponding element described with reference to FIG. 1.

Referring to FIG. 4, according to some aspects, user experience platform 405 provides prompt 410 to machine learning model 415. In some cases, machine learning model 415 generates user journey 420 based on prompt 410. In some cases, user experience platform provides digital content 425 to user 430 according to a touchpoint of user journey 420.

### Content Distribution

A method for content distribution is described with reference to FIGS. 5-10. One or more aspects of the method include obtaining a prompt describing an element of a content distribution campaign; generating, using a machine learning model, a user journey based on the prompt, wherein the user journey includes at least one touchpoint for the content distribution campaign; and providing digital content to a user corresponding to the at least one touchpoint based on the user journey.

In some aspects, the user journey includes a plurality of touchpoints connected by a plurality of edges. In some aspects, each of the plurality of touchpoints corresponds to a stage of the content distribution campaign. In some aspects, the machine learning model is trained using training data including a plurality of user journeys.

Some examples of the method further include simulating, using the machine learning model, one or more instances of the user journey. Some examples further include generating one or more predicted performance values based on the simulation. Some examples of the method further include updating the simulation based on the one or more predicted performance values. Some examples of the method include identifying a user journey path, wherein the simulation is based on the user journey path. In some aspects, the simulation is based on one or more user attributes.

In some aspects, generating the user journey comprises encoding the prompt to obtain a sequence of input tokens and generating a sequence of output tokens based on the sequence of input tokens, wherein the user journey is based on the sequence of output tokens. Some examples of the method further include displaying a graph representing the user journey including a node corresponding to the at least one touchpoint.

FIG. 5 shows an example of a method 500 for content distribution according to aspects of the present disclosure. In some examples, these operations are performed by a system including a processor executing a set of codes to control functional elements of an apparatus. Additionally or alternatively, certain processes are performed using special-purpose hardware. Generally, these operations are performed according to the methods and processes described in accordance with aspects of the present disclosure. In some cases, the operations described herein are composed of various substeps, or are performed in conjunction with other operations.

Referring to FIG. 5, according to an aspect of the present disclosure, a content distribution system (such as the content distribution system described with reference to FIGS. 1 and 4) is used in a content distribution campaign context. In the example shown, a content provider (such as the content provider described with reference to FIG. 1) provides an input to a user interface element. In response to the input, a content distribution apparatus (such as the content distribution apparatus described with reference to FIG. 2) generates a user journey in response to a content provider input. The content distribution apparatus displays a representation of the user journey to the content provider and provides digital content to a user (such as the user described with reference to FIG. 1) according to the user journey.

At operation 505, the content provider provides a content provider input to a user interface element. In some cases, the operations of this step refer to, or are performed by, a content provider as described with reference to FIG. 1. For example, in some cases, the content provider selects a user interface element including a suggestion that a user journey be generated, or provides a text input instructing the content distribution apparatus to generate the user journey.

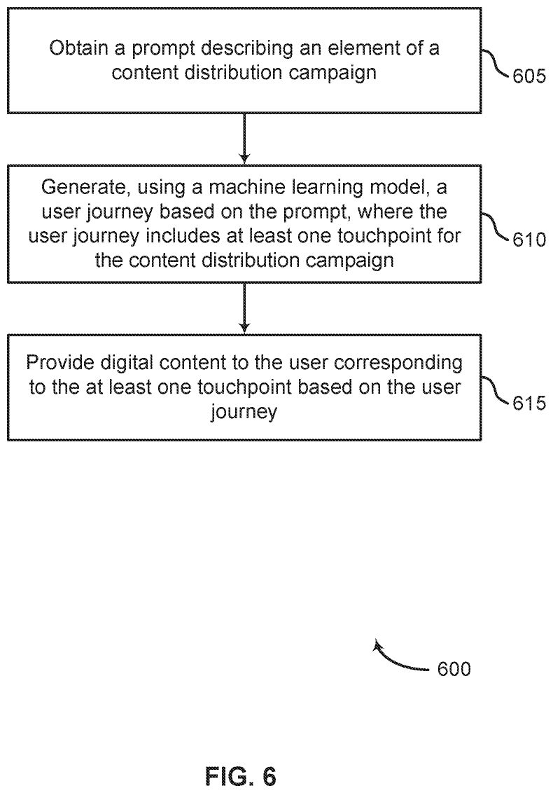

At operation 510, the system generates a user journey in response to the content provider input. In some cases, the operations of this step refer to, or are performed by, a content distribution apparatus as described with reference to FIGS. 1 and 2. For example, in some cases, a user experience platform of the content distribution apparatus (such as the user experience platform described with reference to FIGS. 2 and 4) generates a prompt in response to the content provider input, where the prompt includes the content provider input and context, as described with reference to FIG. 6. In some cases, a machine learning model of the content distribution apparatus (such as the machine learning model described with reference to FIGS. 2 and 4) generates the user journey based on the prompt as described with reference to FIG. 6.

At operation 515, the system displays a visual representation of the user journey to the content provider. In some cases, the operations of this step refer to, or are performed by, a content distribution apparatus as described with reference to FIGS. 1 and 2. For example, in some cases, the content distribution apparatus displays the representation via a user interface as described with reference to FIG. 6.

At operation 520, the system provides content to a user based on the user journey. In some cases, the operations of this step refer to, or are performed by, a content distribution apparatus as described with reference to FIGS. 1 and 2. For example, in some cases, the content distribution apparatus provides digital content to a user according to a touchpoint of the user journey as described with reference to FIG. 6.

FIG. 6 shows an example of a method 600 for providing digital content based on a user journey according to aspects of the present disclosure. In some examples, these operations are performed by a system including a processor executing a set of codes to control functional elements of an apparatus. Additionally or alternatively, certain processes are performed using special-purpose hardware. Generally, these operations are performed according to the methods and processes described in accordance with aspects of the present disclosure. In some cases, the operations described herein are composed of various substeps, or are performed in conjunction with other operations.

Referring to FIG. 6, according to some aspects, a content distribution system (such as the content distribution system described with reference to FIGS. 1 and 4) generates a user journey and distributes content according to the user journey. In some cases, the content distribution system simulates an iteration of the user journey and predicts a performance of the user journey, allowing a content provider to gain confidence before launching a content distribution campaign corresponding to the user journey. In some cases, the content distribution system generates the user journey and/or simulates the user journey based on historical user journey data.

In some cases, the content distribution system optimizes the user journey based on one or more of implicit feedback and explicit feedback from one or more of a content provider and a user. In some cases, a real world behavior and performance of the user journey feeds back to the content distribution system, and the content distribution system rebalances and optimizes the user journey in real time.

In some cases, the content distribution system dynamically provides content based on one or more of content affinities of a content provider, a campaign brief generated by the content distribution system, and information associated with a user segment.

In some cases, a machine learning model (such as the machine learning model described with reference to FIGS. 2 and 4) generates the journey using a sequence-to-sequence-based transformer. In some cases, the machine learning model is trained on a set of historical touchpoints for one or more users. In some cases, the machine learning model is trained on an outcome of a historical user journey, such as an advancement of a user towards a content provider's objective (e.g., a purchase of a product, a sign-up for a subscription, etc.).

In some cases, a user journey comprises a personalized sequence of touchpoints that are expected to fulfill an objective of a content distribution campaign. In some cases, the user journey identifies a communication channel. In some cases, the user journey identifies a timing for one or more touchpoints.

In some cases, the content distribution system simulates one or more iterations of a user journey. In some cases, the content distribution system predicts a performance of a user journey in terms of an advancement of a user at each stage of the user journey towards an achievement of a goal of an associated content distribution campaign.

At operation 605, the system obtains a prompt describing an element of a content distribution campaign. In some cases, the operations of this step refer to, or are performed by, a user experience platform as described with reference to FIGS. 2 and 4.

For example, in some cases, the user experience platform generates the prompt by including context as described herein in the prompt. In some cases, the context includes the element of the content distribution campaign (e.g., an identification of a user segment, a communication channel, a campaign objective, a content element, etc.). In some cases, the prompt incudes an instruction to generate the user journey. In some cases, the user experience platform generates the prompt in a response to a change in context (for example, a content provider navigation to a user interface associated with user journey generation). In some cases, the user experience platform generates the prompt in response to a content provider input (e.g., an input to a user interface element associated with a generation of a user journey, or a text input such as “Show me the journey for this campaign”). In some cases, the prompt incudes the text input. An example of a content provider input for generating a user journey is described with reference to FIG. 7.

At operation 610, the system generates, using a machine learning model, a user journey based on the prompt, where the user journey includes at least one touchpoint for the content distribution campaign. In some cases, the operations of this step refer to, or are performed by, a machine learning model as described with reference to FIGS. 2 and 4.

For example, in some cases, machine learning model includes a large language model trained to generate the user journey based on the prompt. In some cases, the machine learning model includes a transformer trained to generate the user journey based on the prompt. In some cases, generating the user journey includes encoding the prompt to obtain a sequence of input tokens and generating a sequence of output tokens based on the sequence of input tokens, wherein the user journey is based on the sequence of output tokens. In some cases, the machine learning model is trained using training data including a set of user journeys.

In some cases, the user journey includes a set of touchpoints connected by a set of edges. In some cases, the user journey includes a text description of a set of touchpoints connected by a set of edges. In some cases, each of the set of touchpoints corresponds to a stage of the content distribution campaign.

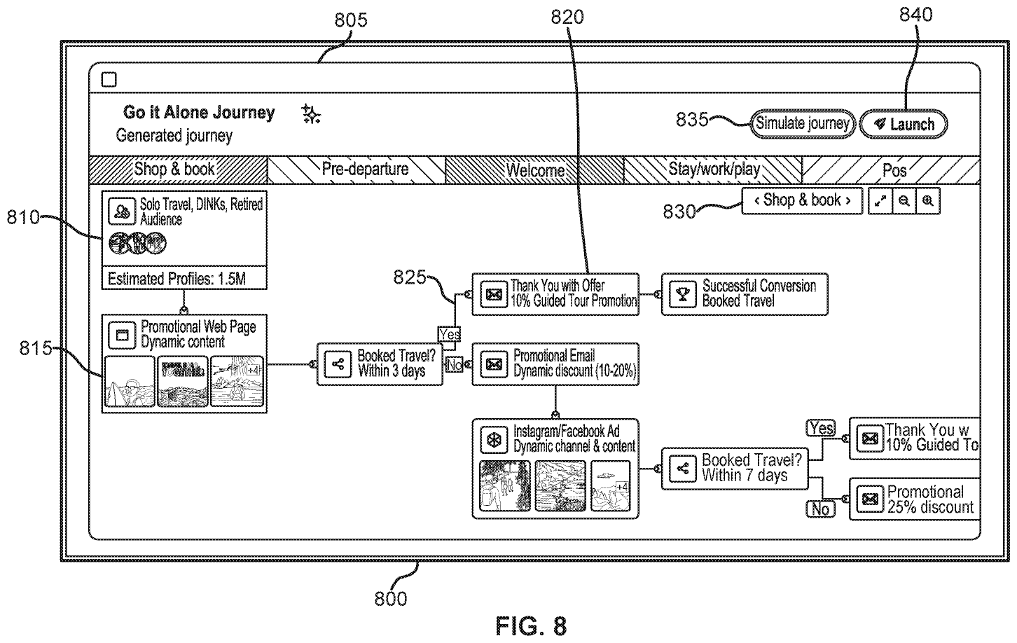

According to some aspects, the user experience platform displays a graph representing the user journey. In some cases, the graph includes a node corresponding to the at least one touchpoint. An example of a graph representing a user journey is described with reference to FIG. 8.

According to some aspects, the machine learning model simulates one or more instances of the user journey. For example, in some cases, in response to a content provider input instructing the content distribution system to simulate a user journey, the user experience platform generates a simulation prompt. In some cases, the simulation prompt incudes context for the simulation (including, for example, content provider data, user segment information, communication channel information, one or more of the user journey, a previously generated user journey, information corresponding to a performance of the previously generated user journey, etc.). In some cases, the simulation prompt includes an instruction to simulate the user journey.

In some cases, the machine learning model simulates the user journey based on the simulation prompt by generating a simulation of the user journey. In some cases, the machine learning model simulates the user journey by predicting a path of a user associated with the user journey through each edge of the user journey, predicting an outcome for the user at each touchpoint of the user journey, and generating a throughput prediction based on the path predictions and the touchpoint predictions, such as how far into the user journey the user is likely to progress, a likelihood of a user segment to drop out of the user journey after a given touchpoint, etc. In some cases, the simulation is based on one or more user attributes.

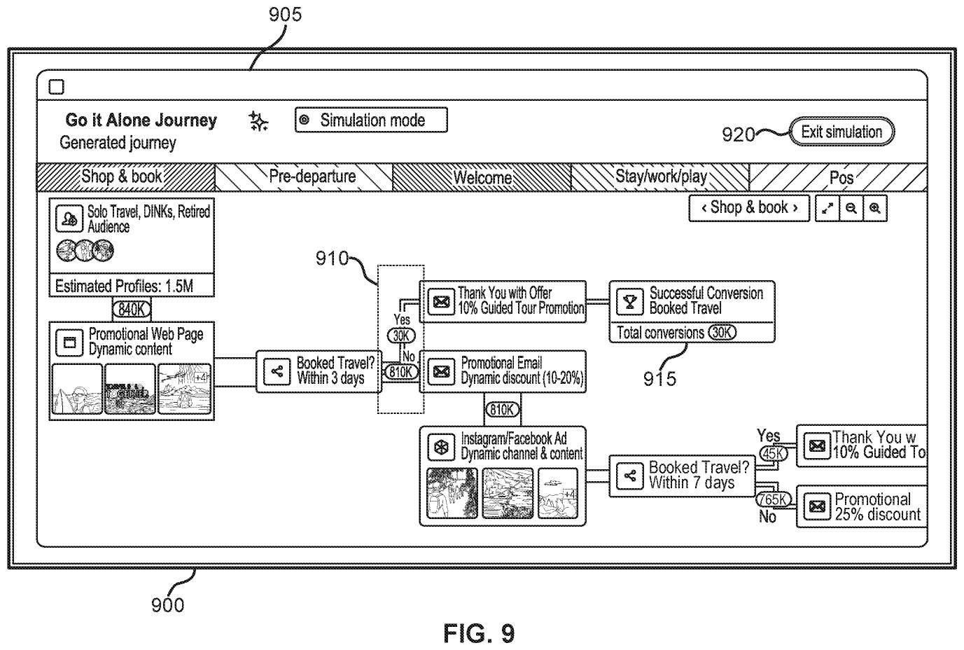

In some cases, the simulation includes a text description of one or more of the predictions for the user journey. In some cases, the simulation includes an instruction or code executable by the user experience platform to generate a representation of the simulation. In some cases, the simulation includes an instruction or code executable by the user experience platform to display the representation of the simulation. An example of a representation of a simulation of a user journey is described with reference to FIG. 9.

In some cases, the machine learning model generates one or more predicted performance values based on the simulation. For example, in some cases, the machine learning model generates a description of a prediction of a specific outcome or metric for the user journey based on the simulation, such as a number of users who will perform an action, a likelihood of members of a user segment to perform an action, etc. In some cases, the machine learning model generates the one or more predicted performance values according to a particular touchpoint in the user journey.

In some cases, the machine learning model generates the one or more predicted performance values based on the simulation prompt. In some cases, the machine learning model generates the one or more predicted performance values in response to a content provider input (for example, to an associated user interface element, or by providing a text input to the user interface). In some cases, the content provider input specifies a touchpoint/outcome for prediction.

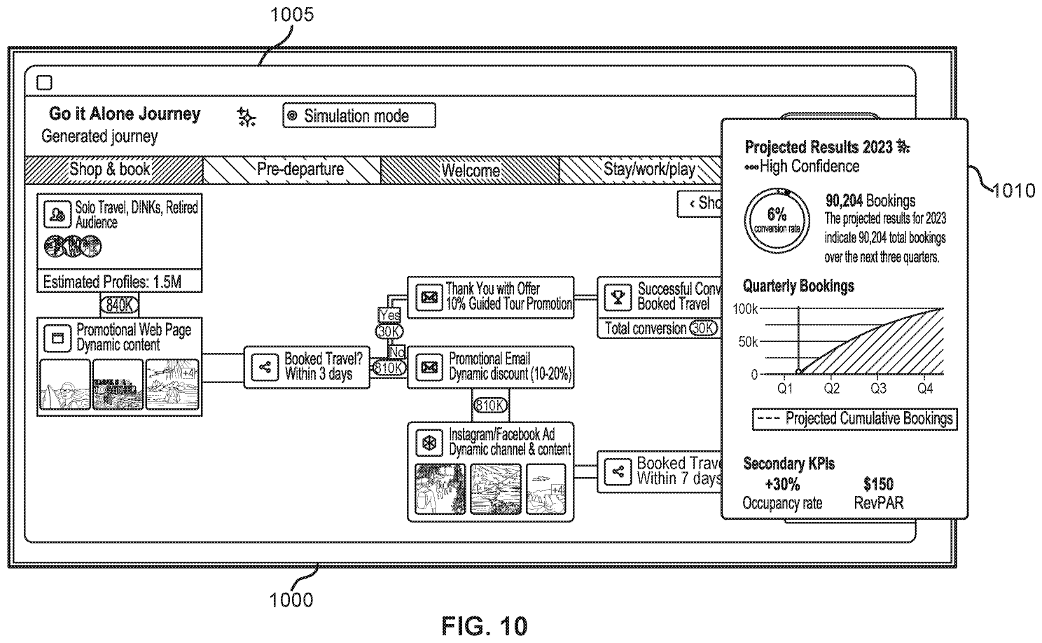

In some cases, the machine learning model generates an instruction or code executable by the user experience platform to generate a representation of the one or more predicted performance values. In some cases, the machine learning model generates an instruction or code executable by the user experience platform to display the representation of the one or more predicted performance values. An example of a representation of one or more predicted performance values is described with reference to FIG. 10.

According to some aspects, the user experience platform generates an updated simulation prompt including the one or more predicted performance values. According to some aspects, the machine learning platform generates an updated simulation based on the updated simulation prompt. In some cases, the user experience platform displays a representation of the updated simulation via the user interface.

At operation 615, the system provides digital content to a user corresponding to the at least one touchpoint based on the user journey. In some cases, the operations of this step refer to, or are performed by, a user experience platform as described with reference to FIGS. 2 and 4. For example, in some cases, the user experience platform is configured to provide the digital content to a user of a user segment corresponding to the user journey when a condition or conditions specified for the touchpoint occur. In some cases, the user experience platform provides the digital content via a digital content channel specified by the user journey for the touchpoint.

FIG. 7 shows an example of a user interface 700 for generating a user journey according to aspects of the present disclosure. User interface 700 is an example of, or includes aspects of, the corresponding element described with reference to FIGS. 2 and 8-10. In one aspect, user interface 700 includes first user interface element 705, prompt element 710, and second user interface element 715.

Referring to FIG. 7, according to some aspects, a content provider (such as the content provider described with reference to FIGS. 1 and 5) instructs a content distribution system (such as the content distribution system described with reference to FIGS. 1 and 4) to generate a user journey via an input to prompt element 710. As shown in FIG. 7, the instruction is an implicit instruction (“Show me the journey for this campaign”), where a user experience platform (such as the user experience platform described with reference to FIGS. 2 and 4) generates a prompt including context (such as information relating to first user interface element 705 and second user interface element 715) such that a machine learning model (such as the machine learning model described with reference to FIGS. 2 and 4) is able to parse the meaning of “this campaign” when generating the user journey.

FIG. 8 shows an example of a user interface 800 for viewing a user journey according to aspects of the present disclosure. User interface 800 is an example of, or includes aspects of, the corresponding element described with reference to FIGS. 2, 7, 9, and 10. In one aspect, user interface 800 includes third user interface element 805. Third user interface element 805 is an example of, or includes aspects of, the corresponding element described with reference to FIGS. 9 and 10.

In one aspect, third user interface element 805 includes user segment element 810, content distribution channel element 815, touchpoint element 820, edge element 825, campaign phase element 830, “Simulate journey” element 835, and “Launch” element 840.

FIG. 8 shows an example of a user interface for displaying a representation of a user journey generated as described with reference to FIG. 6. For example, third user interface element 805 includes a graph for a user journey including a touchpoint element 820 as a node and an edge element 825 connected to touchpoint element 820. In the example of FIG. 8, touchpoint element 820 is a representation of a touchpoint of, from a perspective of a user included in a user segment identified in user segment element 810, receiving a “thank you” message including a discount offer from a user experience platform (such as the user experience platform described with reference to FIGS. 2 and 4) when the user books travel within three days of viewing a content element provided on a promotional web page by the user experience platform identified in content distribution channel element 815.

According to some aspects, campaign phase element 830 allows a content provider (such as the content provider described with reference to FIGS. 1 and 5) to view a representation of a set of touchpoints corresponding to different phases of the user journey. According to some aspects, “Simulate journey” element 835 allows the content provider to instruct the content distribution system to simulate the user journey. According to some aspects, “Launch” element 840 allows the content provider to launch a content distribution campaign corresponding to the user journey.

FIG. 9 shows an example of a user interface 900 for simulating a user journey according to aspects of the present disclosure. User interface 900 is an example of, or includes aspects of, the corresponding element described with reference to FIGS. 2, 7, 8, and 10. In one aspect, user interface 900 includes third user interface element 905.

Third user interface element 905 is an example of, or includes aspects of, the corresponding element described with reference to FIGS. 8 and 10. In one aspect, third user interface element 905 includes first simulation result element 910, second simulation result element 915, and “Exit simulation” element 920.

Referring to FIG. 9, third user interface element 905 is modified to include a representation of a simulation of the user journey represented in third user interface element 905, where the simulation is performed in response to the “Simulate journey” element described with reference to FIG. 8. As shown in FIG. 8, in some cases, the representation of the simulation of the user journey includes a depiction of a prediction of an outcome of various iterations of a user journey (such as first simulation result element 910 and second simulation result element 915) according to branching paths of possibilities included in the user journey. “Exit simulation” element 920 allows the content provider to return to a user interface for displaying the generated user journey.

FIG. 10 shows an example of a user interface 1000 for predicting a performance of a user journey according to aspects of the present disclosure. User interface 1000 is an example of, or includes aspects of, the corresponding element described with reference to FIG. 2, and 7-9. In one aspect, user interface 1000 includes third user interface element 1005 and projected results user interface element 1010. Third user interface element 1005 is an example of, or includes aspects of, the corresponding element described with reference to FIGS. 8 and 9.

Referring to FIG. 10, projected results user interface element 1010 is displayed above third user interface element 1005. As shown in FIG. 10, in some cases, user interface 1000 displays a representation of one or more predicted performance values for a user journey (here, as shown in projected results user interface element 1010, predicted performance values relating to a number of bookings for 2023, a conversion rate, quarterly bookings, and secondary key performance indicators) as described with reference to FIG. 6.

### Training

A method for content distribution is described with reference to FIG. 11. One or more aspects of the method include initializing a machine learning model; obtaining training data including user journey data; and training, using the training data, the machine learning model to generate a user journey based on a prompt.

Some examples of initializing the machine learning model include obtaining a pre-trained machine learning model. Some examples of training the machine learning model include fine-tuning the pre-trained machine learning model.

Some examples of the method further include generating a predicted touchpoint. Some examples further include comparing the predicted touchpoint to a ground-truth touchpoint of the user journey data. Some examples further include computing a loss function based on the comparison, wherein the training is based on the loss function.

FIG. 11 shows an example of a method 1100 for training a machine learning model according to aspects of the present disclosure. In some examples, these operations are performed by a system including a processor executing a set of codes to control functional elements of an apparatus. Additionally or alternatively, certain processes are performed using special-purpose hardware. Generally, these operations are performed according to the methods and processes described in accordance with aspects of the present disclosure. In some cases, the operations described herein are composed of various substeps, or are performed in conjunction with other operations.

At operation 1105, the system initializes a machine learning model. In some cases, the operations of this step refer to, or are performed by, a training component as described with reference to FIG. 2. In some cases, initializing the machine learning model comprises obtaining a pre-trained machine learning model. In some cases, the training component retrieves the pre-trained machine learning model (e.g., parameters for a pre-trained machine learning model) from a database (such as the database described with reference to FIG. 1).

At operation 1110, the system obtains training data including user journey data. In some cases, the operations of this step refer to, or are performed by, a training component as described with reference to FIG. 2. In some cases, the training component obtains the training data from the database.

At operation 1115, the system trains, using the training data, the machine learning model to generate a user journey based on a prompt. In some cases, the operations of this step refer to, or are performed by, a training component as described with reference to FIG. 2.

According to some aspects, the training component generates the prompt. In some cases, the prompt includes the training data. In some cases, the prompt includes an instruction to generate a predicted touchpoint. In some cases, the prompt includes an instruction to generate a predicted outcome for the predicted touchpoint. According to some aspects, the training component provides the prompt to the machine learning model. According to some aspects, the training component provides the prompt to the pre-trained machine learning model.

In some cases, the machine learning model generates a predicted touchpoint based on the prompt. In some cases, the machine learning model generates a predicted outcome for the predicted touchpoint based on the prompt. In some cases, the pre-trained machine learning model generates a predicted touchpoint based on the prompt. In some cases, the pre-trained machine learning model generates a predicted outcome for the predicted touchpoint based on the prompt.

In some cases, the training component compares the predicted touchpoint to a ground-truth touchpoint included in the user journey data. In some cases, the training component compares the predicted outcome for the predicted touchpoint to a ground-truth outcome included in the user journey data. In some cases, the training component computes a loss function based on the comparison.

The term “loss function” refers to a function that impacts how a machine learning model is trained in a supervised learning model. For example, during each training iteration, the output of the machine learning model is compared to the known annotation information in the training data. The loss function provides a value (a “loss”) for how close the predicted annotation data is to the actual annotation data. After computing the loss, the parameters of the model are updated accordingly and a new set of predictions are made during the next iteration.

Supervised learning is one of three basic machine learning paradigms, alongside unsupervised learning and reinforcement learning. Supervised learning is a machine learning technique based on learning a function that maps an input to an output based on example input-output pairs. Supervised learning generates a function for predicting labeled data based on labeled training data consisting of a set of training examples. In some cases, each example is a pair consisting of an input object (typically a vector) and a desired output value (i.e., a single value, or an output vector). In some cases, a supervised learning algorithm analyzes the training data and produces the inferred function, which is used for mapping new examples. In some cases, the learning results in a function that correctly determines the class labels for unseen instances. In other words, the learning algorithm generalizes from the training data to unseen examples.

In some cases, the training component trains the machine learning model by updating the machine learning parameters of the machine learning model according to the loss function. In some cases, the training component trains the machine learning model by fine-tuning the parameters of the pre-trained machine learning model according to the loss function.

The description and drawings described herein represent example configurations and do not represent all the implementations within the scope of the claims. For example, the operations and steps can be rearranged, combined, or otherwise modified. Also, in some cases, structures and devices are represented in the form of block diagrams to represent the relationship between components and avoid obscuring the described concepts. In some cases, similar components or features have the same name but have different reference numbers corresponding to different figures.

Some modifications to the disclosure are readily apparent to those skilled in the art, and the principles defined herein can be applied to other variations without departing from the scope of the disclosure. Thus, the disclosure is not limited to the examples and designs described herein, but is to be accorded the broadest scope consistent with the principles and novel features disclosed herein.

In some embodiments, the described methods are implemented or performed by devices that include a general-purpose processor, a digital signal processor (DSP), an application specific integrated circuit (ASIC), a field programmable gate array (FPGA) or other programmable logic device, discrete gate or transistor logic, discrete hardware components, or any combination thereof. In some embodiments, a general-purpose processor is a microprocessor, a conventional processor, controller, microcontroller, or state machine. In some embodiments, a processor is implemented as a combination of computing devices (e.g., a combination of a DSP and a microprocessor, multiple microprocessors, one or more microprocessors in conjunction with a DSP core, or any other such configuration). Thus, in some embodiments, the functions described herein are implemented in hardware or software and are executed by a processor, firmware, or any combination thereof. In some embodiments, if implemented in software executed by a processor, the functions are stored in the form of instructions or code on a computer-readable medium.

Computer-readable media includes both non-transitory computer storage media and communication media including any medium that facilitates transfer of code or data. In some embodiments, a non-transitory storage medium is any available medium that is accessible by a computer. For example, in some cases, non-transitory computer-readable media comprise random access memory (RAM), read-only memory (ROM), electrically erasable programmable read-only memory (EEPROM), compact disk (CD) or other optical disk storage, magnetic disk storage, or any other non-transitory medium for carrying or storing data or code.

Also, in some embodiments, connecting components are properly termed computer-readable media. For example, if code or data is transmitted from a website, server, or other remote source using a coaxial cable, fiber optic cable, twisted pair, digital subscriber line (DSL), or wireless technology such as infrared, radio, or microwave signals, then the coaxial cable, fiber optic cable, twisted pair, DSL, or wireless technology are included in the definition of medium. Combinations of media are also included within the scope of computer-readable media.

In this disclosure and the following claims, the word “or” indicates an inclusive list such that, for example, the list of X, Y, or Z means X or Y or Z or XY or XZ or YZ or XYZ. Also the phrase “based on” is not used to represent a closed set of conditions. For example, a step that is described as “based on condition A” can be based on both condition A and condition B. In other words, the phrase “based on” shall be construed to mean “based at least in part on.” Also, the words “a” or “an” indicate “at least one.”

What is claimed is:

1. A method for content distribution, comprising:
obtaining, by a user experience platform, a prompt describing an element of a content distribution campaign;
generating, using a machine learning model, a user journey based on the prompt, wherein the user journey includes at least one touchpoint for the content distribution campaign; and
providing, by the user experience platform, digital content to a user corresponding to the at least one touchpoint based on the user journey.

2. The method of claim 1, wherein:
the user journey includes a plurality of touchpoints connected by a plurality of edges.

3. The method of claim 2, wherein:
each of the plurality of touchpoints corresponds to a stage of the content distribution campaign.

4. The method of claim 1, wherein:
the machine learning model is trained using training data including a plurality of user journeys.

5. The method of claim 1, further comprising:
simulating, using the machine learning model, one or more instances of the user journey; and
generating, using the machine learning model, one or more predicted performance values based on the simulation.

6. The method of claim 5, further comprising:
updating, by the machine learning model, the simulation based on the one or more predicted performance values.

7. The method of claim 5, further comprising:
identifying, by the machine learning model, a user journey path, wherein the simulation is based on the user journey path.

8. The method of claim 5, wherein:
the simulation is based on one or more user attributes.

9. The method of claim 1, wherein:
generating the user journey comprises encoding the prompt to obtain a sequence of input tokens and generating a sequence of output tokens based on the sequence of input tokens, wherein the user journey is based on the sequence of output tokens.

10. The method of claim 1, further comprising:
displaying, by the user experience platform, a graph representing the user journey including a node corresponding to the at least one touchpoint.

11. A method for content distribution, comprising:
initializing, by a training component, a machine learning model;
obtaining, by the training component, training data including user journey data; and
training, by the training component using the training data, the machine learning model to generate a user journey based on a prompt.

12. The method of claim 11, wherein:
initializing the machine learning model comprises obtaining a pre-trained machine learning model; and
training the machine learning model comprises fine-tuning the pre-trained machine learning model.

13. The method of claim 11, further comprising:
generating, by the machine learning model, a predicted touchpoint;
comparing, by the training component, the predicted touchpoint to a ground-truth touchpoint of the user journey data; and
computing, by the training component, a loss function based on the comparison, wherein the training is based on the loss function.

14. An apparatus for content distribution, comprising:
one or more processors;
one or more memory components storing instructions executable by the one or more processors; and
a machine learning model comprising parameters stored in the one or more memory components and trained to generate a user journey based on a prompt, wherein the user journey includes at least one touchpoint for a content distribution campaign.

15. The apparatus of claim 14, further comprising:
a user experience platform configured to generate digital content corresponding to the at least one touchpoint based on the user journey.

16. The apparatus of claim 14, wherein:
the machine learning model comprises a transformer architecture.

17. The apparatus of claim 14, wherein:
the machine learning model comprises a large language model.

18. The apparatus of claim 14, further comprising:
a user interface configured to display a graph representing the user journey including a node corresponding to the at least one touchpoint.

19. The apparatus of claim 14, wherein:
the machine learning model is further trained to simulate one or more instances of the user journey and to generate one or more predicted performance values based on the simulation.

20. The apparatus of claim 14, further comprising:
a training component configured to train the machine learning model to generate a user journey.
